(19) United States
(12) Patent Application Publication
(10) Pub. No.: US 2025/0070102 A1
(43) Pub. Date: Feb. 27, 2025

(54) POWER CONVERTER PACKAGES, APPARATUS FOR POWER CONVERSION, AND METHODS FOR INTEGRATED CIRCUIT PACKAGING

(71) Applicant: Murata Manufacturing Co., Ltd., Nagaokakyo-shi (JP)

(72) Inventors: David Giuliano, Beford, NH (US); Stephen John Allen, San Diego, CA (US)

(21) Appl. No.: 18/945,445

(22) Filed: Nov. 12, 2024

Related U.S. Application Data
(63) Continuation of application No. PCT/US2023/066882, filed on May 11, 2023.
(60) Provisional application No. 63/364,569, filed on May 12, 2022.
(60) Provisional application No. 63/364,674, filed on May 13, 2022.
(60) Provisional application No. 63/366,773, filed on Jun. 21, 2022.

(51) Int. Cl. H01L 25/16; H01L 23/00; H01L 23/373; H01L 23/48; H02M 3/00; H02M 3/07

(52) U.S. Cl. CPC H01L 25/16; H01L 23/373; H01L 23/481; H01L 24/09; H01L 28/40; H02M 3/003; H02M 3/077; H01L 28/10; H01L 2224/09181

(57) ABSTRACT

Disclosed embodiments may include a power converter package including devices stacked vertically. The devices include a first device and a second device. The first device includes a first switched capacitor circuit and provides first bottom bonding contacts on one surface and first top bonding contacts on another surface opposite the one surface, and one or more through-vias connecting corresponding one or more of the first bottom bonding contacts and corresponding one or more of the first top bonding contacts. The second device includes a second switched capacitor circuit and provides second bottom bonding contacts on one surface to be electrically connected to the first top bonding contacts of the first device. Input terminals of the first and switched capacitor circuits are electrically connected to each other, and output terminals of the first and switched capacitor circuits are electrically connected to each other.

### CROSS-REFERENCE TO RELATED APPLICATIONS

This application is a continuation of International Patent Application No. PCT/US2023/066882 filed May 11, 2023 and entitled “POWER CONVERTER PACKAGES, APPARATUS FOR POWER CONVERSION, AND METHODS FOR INTEGRATED CIRCUIT PACKAGING,” which claims priority to and benefit of U.S. Provisional Patent Application No. 63/364,569, filed on May 12, 2022 and entitled “POWER CONVERTER PACKAGES, APPARATUS FOR POWER CONVERSION, AND METHODS FOR INTEGRATED CIRCUIT PACKAGING,” and U.S. Provisional Patent Application No. 63/364,674, filed on May 13, 2022 and entitled “APPARATUS AND METHODS OF FABRICATING A SWITCHED CAPACITOR CIRCUIT,” and U.S. Provisional Patent Application No. 63/366,773, filed on Jun. 21, 2022 and entitled “THREE-DIMENSIONAL (3D) PACKAGES AND METHODS FOR 3D PACKAGING,” all of which are incorporated herein by reference in their entirety.

### TECHNICAL FIELD

The present disclosure generally relates to power electronic devices. More particularly, the present disclosure relates to power converter packages.

### BACKGROUND

Modern-day central processing units (CPUs) evolve to deliver greater computing performance, such as artificial intelligence (AI) processing and cloud-computing applications, which leads to an escalation in power demand from a power supply. As a result, power converters in the power supply may occupy a considerable space to meet the increasing current requirements of the CPUs. Accordingly, designing a compact and high-density power converter to reduce the required circuit area, while meeting increased current and space requirements has become a challenge in the field.

In addition, many power converters, such as charge pump converters, include switches forming a switch network and one or more capacitors to achieve the power conversion and regulate an output voltage or current by switching energy storage elements (e.g., capacitors and/or inductors) between different electrical configurations. However, such operations often generate significant heat and result in thermal hotspots due to high-power devices within the packages.

### SUMMARY

Embodiments of the present disclosure provide a power converter package. The power converter package includes devices stacked vertically. The devices include a first device and a second device. The first device includes a first switched capacitor circuit and provides first bottom bonding contacts on one surface and first top bonding contacts on another surface opposite the one surface, and one or more through-vias connecting corresponding one or more of the first bottom bonding contacts and corresponding one or more of the first top bonding contacts. The second device includes a second switched capacitor circuit and provides second bottom bonding contacts on one surface to be electrically connected to the first top bonding contacts of the first device. Input terminals of the first and switched capacitor circuits are electrically connected to each other, and output terminals of the first and switched capacitor circuits are electrically connected to each other.

Embodiments of the present disclosure provide an apparatus for power conversion. The apparatus includes a plurality of switched capacitor circuits respectively arranged in a plurality of integrated circuit packages stacked vertically. The switched capacitor circuits are coupled in parallel to convert a first voltage to a second voltage. At least one package in the plurality of integrated circuit packages includes: bottom bonding contacts on one surface providing connections to a substrate or an adjacent lower package stacked under the package; top bonding contacts on another surface opposite the one surface providing connections to an adjacent upper package stacked over the package; and one or more through-vias connecting corresponding one or more of the bottom bonding contacts and corresponding one or more of the top bonding contacts.

Embodiments of the present disclosure provide a method for integrated circuit packaging. The method includes: stacking a plurality of switched capacitor circuits respectively in a plurality of sub-packages vertically by: bonding first bottom bonding contacts placed on one surface of a first sub-package to a substrate or an adjacent lower sub-package stacked under the first sub-package, the first sub-package including a first switched capacitor circuit; and bonding first top bonding contacts placed on another surface opposite the one surface of the first sub-package to second bottom bonding contacts placed on one surface of a second sub-package, the second sub-package including a second switched capacitor circuit or a heat spreader layer, corresponding one or more of the first bottom bonding contacts and corresponding one or more of the first top bonding contacts being connected by one or more through-vias.

Additional features and advantages of the disclosed embodiments will be set forth in part in the following description, and in part will be apparent from the description, or may be learned by practice of the embodiments. The features and advantages of the disclosed embodiments may be realized and attained by the elements and combinations set forth in the claims.

### BRIEF DESCRIPTION OF THE DRAWINGS

Embodiments and various aspects of the present disclosure are illustrated in the following detailed description and the accompanying figures. It is noted that, in accordance with standard practice in the industry, various features are not drawn to scale. In fact, the dimensions of the various features may be arbitrarily increased or reduced for clarity of discussion.

FIG. 1 is a diagram illustrating an exemplary power converter, in accordance with some embodiments of the present disclosure.

FIG. 2 is a diagram illustrating an exemplary switched capacitor circuit, in accordance with some embodiments of the present disclosure.

FIG. 3 is a diagram illustrating an exemplary power converter package, in accordance with some embodiments of the present disclosure.

FIG. 4A is a diagram illustrating an exemplary device, in accordance with some embodiments of the present disclosure.

FIG. 4B is a side view of relative spatial arrangement of switches and capacitors formed in the device of FIG. 4A, in accordance with some embodiments of the present disclosure.

FIG. 4C is a bottom view of relative spatial arrangement of switches and capacitors formed in the device of FIG. 4A, in accordance with some embodiments of the present disclosure.

FIG. 4D is a top view of relative spatial arrangement of switches and capacitors formed in the device of FIG. 4A, in accordance with some embodiments of the present disclosure.

FIG. 5 is a diagram illustrating another exemplary device, in accordance with some embodiments of the present disclosure.

FIG. 6 is a diagram illustrating another exemplary device including heat spreader layers, in accordance with some embodiments of the present disclosure.

FIG. 7 is a diagram illustrating another exemplary power converter package, in accordance with some embodiments of the present disclosure.

FIG. 8 is a diagram illustrating another exemplary power converter package, in accordance with some embodiments of the present disclosure.

FIG. 9 is a diagram illustrating another exemplary power converter, in accordance with some embodiments of the present disclosure.

FIG. 10 is a diagram illustrating an exemplary multi-level power converter circuit, in accordance with some embodiments of the present disclosure.

FIG. 11 is a diagram illustrating an exemplary device, in accordance with some embodiments of the present disclosure.

FIG. 12 is a flowchart of a method for integrated circuit packaging, in accordance with some embodiments of the present disclosure.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this document, the term “coupled” may also be termed as “electrically coupled”, and the term “connected” may be termed as “electrically connected”. “Coupled” and “connected” may also be used to indicate that two or more elements cooperate or interact with each other.

Various embodiments of the present disclosure will be described with respect to embodiments in a specific context, namely a charge pump circuit. As used in this disclosure, the term “charge pump” refers to a switched-capacitor network configured to convert an input voltage to an output voltage. Examples of such charge pumps include cascade multiplier, Dickson, Ladder, Series-Parallel, Fibonacci, and Doubler switched-capacitor networks, all of which may be configured as a multi-phase or a single-phase network.

The concepts in the disclosure may also apply, however, to other types of power converters. Power converters which convert a higher input voltage power source to a lower output voltage level are commonly known as step-down or buck converters, because the converter is “bucking” the input voltage. Power converters which convert a lower input voltage power source to a higher output voltage level are commonly known as step-up or boost converters, because the converter is “boosting” the input voltage. In addition, some power converters, commonly known as “buck-boost converters,” may be configured to convert the input voltage power source to the output voltage with a wide range, in which the output voltage may be either higher than or lower than the input voltage. In various embodiments, a power converter may be bi-directional, being either a step-up or a step-down converter depending on how a power source is connected to the converter. In some embodiments, an AC-DC power converter can be built up from a DC-DC power converter by, for example, first rectifying an AC input voltage to a DC voltage and then applying the DC voltage to a DC-DC power converter.

High-density, integrated switched-capacitor power converters may be desirable in applications including, but not limited to, data centers or portable electronic devices such as tablets, cell phones, or hand-held computers, and IoT (Internet of Things) devices. In various embodiments of the present disclosure, power converter packages and methods of making high-density switched-capacitor power converters are disclosed.

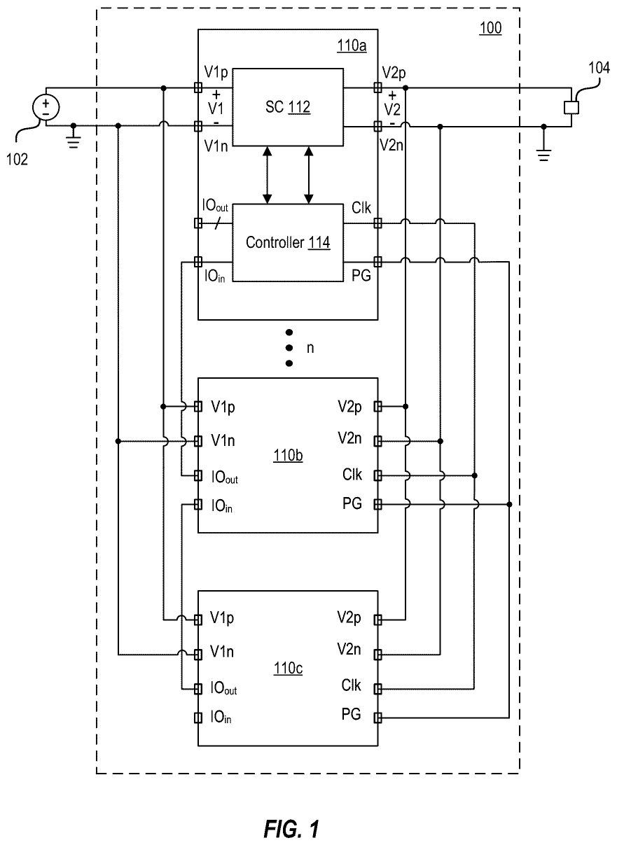

Reference is made to FIG. 1. FIG. 1 is a diagram illustrating an exemplary power converter 100, in accordance with some embodiments of the present disclosure. As shown in FIG. 1, the power converter 100 may include multiple devices 110a, 110b, and 110c coupled to each other. In a preferred embodiment, a power module may include one or more of the devices 110a, 110b, and 110c. For example, each device may provide a power module. As used herein, a power module may refer to a physical unit or apparatus containing power and electronic components of a power converter circuit. It is noted that the number of the devices 110a, 110b, and 110c may vary in different embodiments, and FIG. 1 is a simplified example and not meant to limit the present disclosure. The device 110a includes a switched capacitor circuit 112 (also known as a charge pump circuit) and a controller circuit 114 configured to control the operation of the switched capacitor circuit 112. Specifically, the controller circuit 114 may include control circuitry, timing circuitry, protection circuitry, and gate drivers, among other components, configured to operate the switches, which in turn may change the electrical configuration of the switched capacitor circuit 112 between a first mode/state or second mode/state.

In the embodiments of FIG. 1, the power converter 100 is configured to receive energy from a voltage source 102 at an input voltage V1 between input terminals V1p and V1n respectively and deliver that energy to an output load 104 with an output voltage V2 between output terminals V2p and V2n respectively. In some embodiments, the input voltage V1 may be higher than the output voltage V2. The devices 110a, 110b, and 110c each includes a power converting circuit (e.g., switched capacitor circuit 112) configured to convert the input voltage V1 to the output voltage V2. As shown in the embodiments of FIG. 1, by using multiple power modules (e.g., including multiple devices 110a, 110b, and 110c) with input terminals V1p and Vin of the switched capacitor circuits connected together and output terminals V2p and V2n of the switched capacitor circuits connected together in the power converter 100, the power converter 100 may achieve higher power rating based on low-cost and low-rating devices. Accordingly, the modular design also offers the flexibility and scalability of the power converting circuits to meet different needs in power supply systems in various applications.

In some embodiments, the devices 110a, 110b, and 110c may respectively include corresponding switched capacitor circuit 112 and individual controller circuit 114, but the present disclosure is not limited thereto. In some embodiments, switched capacitor circuits 112 in the devices 110a, 110b, and 110c may be controlled by an external master controller coupled to the devices 110a, 110b, and 110c. In some other embodiments, the power converter 100 may include one internal master controller (e.g., controller circuit 114 in the device 110a), and one or more slave controllers (e.g., controller circuit 114 in the devices 110b and 110c) configured to communicate with the internal master controller. In addition, one or more of the power modules in the power converter 100 may support Power Management Bus (PMBUS) Communications protocol, while remaining power modules are “light” power modules having a simpler design without PMBUS and/or telemetry circuits.

In some embodiments, the controller circuit 114 may be fabricated on a semiconductor substrate such as silicon, gallium nitride (GaN), Silicon-On-Insulator (SOI), Silicon-On-Sapphire (SOS), Silicon-On-Glass (SOG), Silicon-On-Quartz (SOQ), among other substrates, using semiconductor processing techniques compatible with complementary metal oxide semiconductor (CMOS) fabrication. The controller circuit 114 may be physically integrated with the switches in the switched capacitor circuit 112 on the same substrate (e.g., an on-chip configuration) or as an off-chip component configured to operate the switches in the switched capacitor circuit 112.

As shown in FIG. 1, in some embodiments, input terminals V1p, Vin and output terminals V2p, V2n of the switched capacitor circuit 112 in each devices 110a, 110b, and 110c are coupled. In addition, some input terminals of the controller circuit 114, such as a PG terminal for receiving a “Power Good” (PG) signal or a CLK terminal for receiving a clock signal, may also be coupled in parallel, such that the devices 110a, 110b, and 110c receive the same PG signal and the same clock signal. Some other terminals, such as I/O pins IOᵢₙ and IOₒᵤₜ of the devices 110a, 110b, and 110c, may be coupled in series to facilitate the circuit operations. In the present disclosure, the terms “node” and “terminal” may be used interchangeably.

In various embodiments of the present disclosures, for applications where the horizontal size of the circuit is limited, the devices 110a, 110b, and 110c including charge pump circuits can be stacked vertically in a package to provide high power density for the power converter 100. For example, central processing units (CPUs) in laptops or in datacenters may provide sufficient height margins (e.g., approximately 2-9 mm, or approximately 7-22 mm), allowing low profile charge pump power modules to be stacked vertically in a z-direction. Thus, with increased total height, the area occupied by the charge pump circuit on the horizontal surface (i.e., the xy-plane) can be reduced, and the footprint is also saved accordingly.

Compared to the charge pump power module in the present embodiments, a buck converter power module typically has a relatively high-profile inductor, such as a wire-wound inductor. Particularly, the inductor is usually the largest and tallest component in the traditional module, and the bottleneck of reducing the module height in the z-direction. Traditional buck converters would not be stacked due to the height of the large inductor, and such vertically-stacked buck converter power modules would exceed the height constraint and thus are undesired for power supply applications for CPUs in laptops or in datacenters. On the other hand, with the switched-capacitor architecture in the present embodiments, low profile (e.g., approximately 1 mm) charge pump power modules are suitable for stacking in various power supply applications.

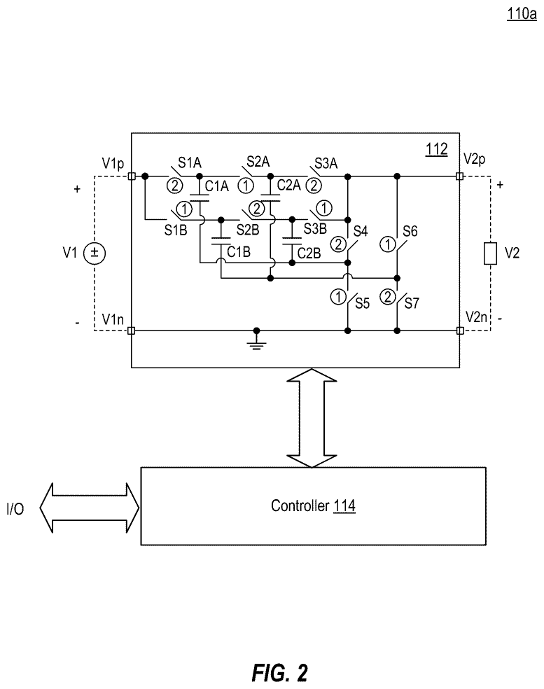

FIG. 2 is a diagram illustrating an exemplary switched capacitor circuit 112 in the device 110a, in accordance with some embodiments of the present disclosure. As shown in FIG. 2, in some embodiments, the switched capacitor circuit 112 may be a two-phase switched-capacitor power converter including switches S1A, S2A, S3A, S1B, S2B, and S3B, switches S4, S5, and S6, and S7, and capacitors C1A, C2A, C1B, and C2B, but the present disclosure is not limited thereto. It is appreciated that the switched capacitor circuit 112 may be single phase or multiple phase, and designed based on a desired conversion ratio.

In the example shown in FIG. 2, the switched capacitor circuit 112 may be configured to receive energy from an input voltage source at the high input voltage V1 via input terminals V1p, V1n, and deliver that energy to an output load at the low output voltage V2 via output terminals V2p, V2n. The controller circuit 114 operates in response to one or more I/O signals, which may be digital communication signals, to control the switched capacitor circuit 112. The controller circuit 114 coupled to the switched capacitor circuit 112 is configured to control switches S1A-S3A, S1B-S3B, and S4-S7 to be on or off accordingly to achieve the power conversion. In some embodiments, a 3:1 transformation ratio may be obtained. Switches S1A, S2A, and S3A may be referred to as “stack” switches for one phase, and switches S1B, S2B, and S3B may be referred to as “stack” switches for the other phase. Switches S4, S5, S6, and S7 may be referred to as “phase” switches, which are shared by two phases in the present embodiment. In some other examples, different transformation ratios (e.g., a 2:1 transformation ratio or a 4:1 transformation ratio) may be obtained by using different numbers of capacitors and different numbers of switches. As the magnitude of the desired transformation ratio increases, the number of capacitors and switches used in a power converter may increase.

During the operation, switches S1B, S2A, S3B, S5, and S6, which are marked as group 1 in FIG. 2, and the switches S1A, S2B, S3A, S4, and S7, which are marked as group 2 in FIG. 2, may be in complementary states. For example, in a first switch state, the switches S1B, S2A, S3B, S5, and S6 may be open and the switches S1A, S2B, S3A, S4, and S7 may be closed, in response to the commands from the controller circuit 114. In a second switch state following the first switch state, the switches S1B, S2A, S3B, S5, and S6 may be closed and the switches S1A, S2B, S3A, S4, and S7 may be open, in response to the commands from the controller circuit 114. Furthermore, a dead-time interval may exist between the first switch state and the second switch state. During the dead-time interval, all the switches are open, which ensures a clean transition between the two switch states. It would be understood that the present disclosure is not limited to such a ratio or type of conversion circuit. In various embodiments, a step-down or a step-up configuration may be applied to all possible charge pump ratios.

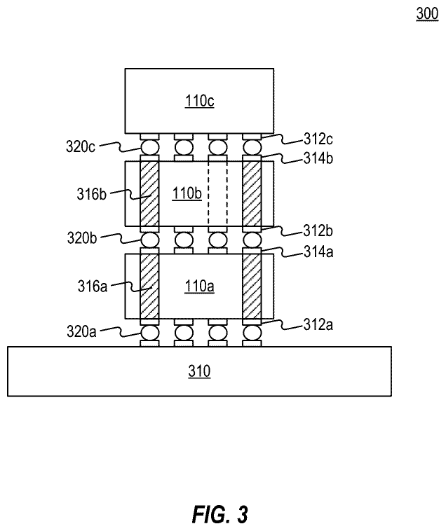

FIG. 3 is a diagram illustrating an exemplary power converter package 300, in accordance with some embodiments of the present disclosure. The power converter package 300 includes multiple integrated circuit packages (e.g., devices 110a, 110b, and 110c) stacked vertically to increase the power density, without increasing the overall package area. As used herein, a “bottom” layer is the layer closest to a substrate providing an electrical interface and the “top” layer is the layer furthest from the substrate. As shown in FIG. 3, the device 110a at the bottom layer may be a bottom package which provides bottom bonding contacts 312a on one surface (e.g., a bottom surface), and top bonding contacts 314a on another surface (e.g., a top surface) opposite the surface having bottom bonding contacts 312a. One or more through-vias 316a of the device 110a connect corresponding bottom bonding contact(s) 312a and corresponding top bonding contact(s) 314a.

Similarly, the device 110b at an intermediate layer may be an intermediate package which provides bottom bonding contacts 312b on a bottom surface, and top bonding contacts 314b on a top surface opposite the bottom surface, with one or more through-vias 316b connecting corresponding bottom bonding contact(s) 312b and corresponding top bonding contact(s) 314b. The device 110c at a top layer may be a top package which provides bottom bonding contacts 312c on a bottom surface. Alternatively stated, in the embodiments of FIG. 3, bottom bonding contacts on one surface of the package provide connections to a substrate or an adjacent lower package stacked under the package, and top bonding contacts on an opposite surface provide connections to an adjacent upper package stacked over the package.

It is noted that, in some embodiments, the top package may be a stackable package or a non-stackable package. In other words, while the device 110c at the top layer may provide top bonding contacts on the top surface, in some other embodiments, the device 110c may only provide bottom bonding contacts 312c. It is also noted that, in various embodiments, depending on the application, the orientation of the non-stackable package and stackable package(s) may be varied in the power converter package 300.

As shown in FIG. 3, the devices 110a, 110b, and 110c are stacked on each other through bondings 320a, 320b, and 320c, which may be electrical bonding (e.g., bumps), thermo-compression bonding, or a hybrid bonding between two adjacent packages. In some embodiments, the bondings 320a, 320b, and 320c may include electrically-conductive bumps, which conduct both heat and electrical signals, and thermally-conductive bumps, which are dedicated to heat transfer only. Particularly, bondings 320a are configured to bond the bottom bonding contacts 312a in the bottom layer to a substrate, such as a main printed circuit board (PCB) 310. Bondings 320b and 320c are configured to bond the top bonding contacts placed on the top surface of the package in one layer to corresponding bottom bonding contacts placed on the bottom surface of another package in an adjacent layer. The bondings 320a, 320b, and 320c, and through-vias 316a and 316b provide electrical connections between the stacked devices 110a, 110b, and 110c. Accordingly, the stacked devices 110a, 110b, and 110c in FIG. 3 can form the power converter 100 in FIG. 1, in which the switched capacitor circuits in different modules are electrically connected in parallel to each other.

As discussed above, one or more controller circuits configured to control operation of the switched capacitor circuits can be arranged in the devices 110a, 110b, and 110c. In some embodiments, a master controller circuit can be arranged in the bottom package (e.g., device 110a), and slave controller circuit(s) can be arranged in one or more intermediate packages (e.g., device 110b) or in the top package (e.g., device 110c). The slave controller circuit(s) may be electrically connected with the master controller circuit arranged in the bottom package through corresponding bottom bonding contacts 312a-312c and top bonding contacts 314a and 314b of the integrated circuit packages.

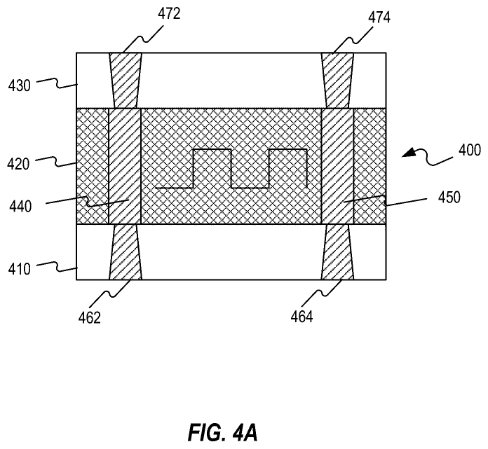

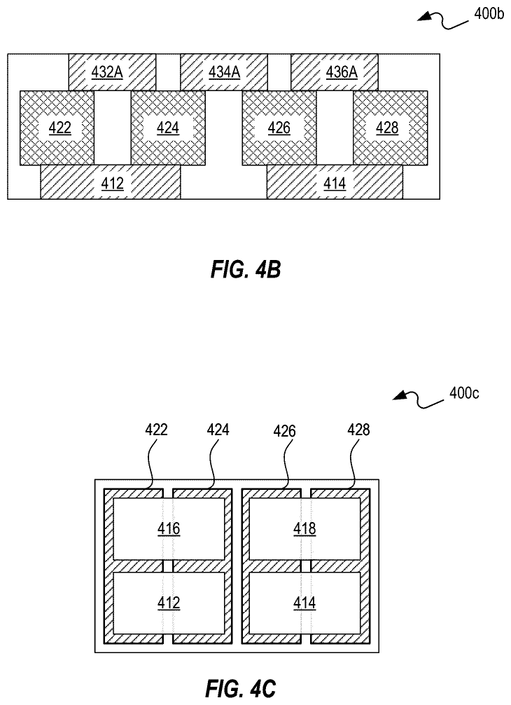

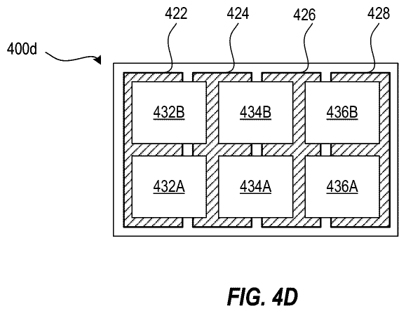

FIG. 4A is a diagram illustrating an exemplary device 400, in accordance with some embodiments of the present disclosure. The device 400 shown in FIG. 4A may be used to implement any of the devices 110a, 110b, and 110c in the power converter package 300 in FIG. 3. As shown in FIG. 4A, the device 400 is wafer-level stacked and includes a first active device layer 410, a passive device layer 420 stacked above the first active device layer 410, and a second active device layer 430 stacked above the passive device layer 420. One or more through-vias 440 and 450 are formed and extend elevationally through the first active device layer 410, the passive device layer 420 and the second active device layer 430.

In some embodiments, the first active device layer 410 includes first switches (e.g., phase switches) of the switched capacitor circuit, and the second active device layer 430 includes second switches (e.g., stack switches) of the switched capacitor circuit. The passive device layer 420 between two active device layers 410 and 430 includes charge pump capacitors of the switched capacitor circuit. For example, the passive device layer 420 may be a glass wafer/panel including the charge pump capacitors. The device 400 provides bottom bonding contacts 462 and 464 on a bottom surface and top bonding contacts 472 and 474 on a top surface opposite the bottom surface for electrical connections to other devices stacked above or below the device 400. As shown in FIG. 4A, through-vias 440 and 450 may be configured to connect corresponding bottom bonding contacts 462 and 464 and top bonding contacts 472 and 474.

Reference is made to FIGS. 4B-4D for better understanding of the present disclosure. FIGS. 4B, 4C, and 4D are a side view 400b, a bottom view 400c, and a top view 400d, respectively, of relative spatial arrangement of switches and capacitors formed in the device 400 of FIG. 4A, in accordance with some embodiments of the present disclosure. In the embodiments of FIGS. 4B-4D, stack switches 432A-436A and 432B-436B, phase switches 412, 414, 416, and 418, and capacitors 422, 424, 426, and 428 of a switched capacitor circuit can be formed in the layers in the device 400. Due to the region from which the cross-section has been selected, stack switches 432B-436B and phase switches 416 and 418 are not shown in FIG. 4B.

As shown in FIG. 4B, capacitors 422, 424, 426, and 428 may be arranged coplanar with each other and between stack switches 432A-436A and 432B-436B and phase switches 412, 414, 416, and 418. As shown in FIGS. 4B and 4C, capacitors 422, 424, 426, and 428 may be formed in a passive device layer (e.g., passive device layer 420 of FIG. 4A), and phase switches 412, 414, 416, and 418 may be formed in a first switch layer (e.g., first active device layer 410 of FIG. 4A) under the passive device layer. As shown in FIGS. 4B and 4D, stack switches 432A-436A and 432B-436B may be formed in a second switch layer (e.g., second active device layer 430 of FIG. 4A) over the passive device layer.

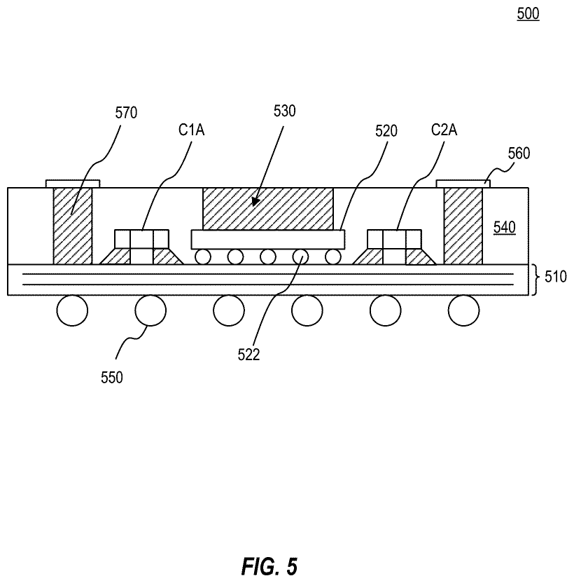

FIG. 5 is a diagram illustrating another exemplary device 500, in accordance with some embodiments of the present disclosure. The device 500 includes a substrate 510 supporting capacitors C1A, C2A, C1B, and C2B, and one or more dies 520 (e.g., silicon dies), which collectively form a switched capacitor circuit. An encapsulant 540 may be deposited over the capacitors C1A, C2A, C1B, and C2B and the one or more dies 520 to encapsulate the switched capacitor circuit at least partially. Through-vias 570 extend through the encapsulant 540 and positioned in correspondence with top bonding contacts 560. For example, a compression molding process may be used to encapsulate the one or more dies 520 and other components with a thermally conductive mold compound.

The substrate 510 may be an FR-4 PCB or a patterned leadframe electrically coupled to bumps 550 for routing power and signals. In various embodiments, the bumps 550 may be solder bumps, copper pillars, copper stud bumps, golden stud bumps, etc., providing electrical communication between the device 500 and any external components. In some embodiments, the patterned leadframe is applied with a solder mask coating to avoid over-collapsing during the soldering process. The solder mask may be applied over leads, and formed with openings corresponding to conductive bumps 550 respectively. Due to the region from which the cross-section has been selected, some capacitors (e.g., capacitors C1B and C2B) in the device 500 may not be shown in FIG. 5.

As shown in FIG. 5, the capacitors C1A, C2A, C1B, and C2B, and one or more dies 520 can be mounted on the substrate 510. Electrically conductive bumps 522 are configured to provide electrical communication between the die(s) 520 and the capacitors C1A, C2A, C1B, and C2B. One or more heat spreaders 530 may be disposed over the one or more dies 520 to facilitate the heat transfer and dissipate the heat generated in the one or more dies 520 during the operations. In some embodiments, the one or more dies 520 may include a stack die containing stack switches (e.g., switches S1A, S1B, S2A, S2B, S3A, and S3B of FIG. 2) and a phase die containing phase switches (e.g., switches S4-S7 of FIG. 2). In some other embodiments, stack switches and phase switches may be integrated in the same die. It would be appreciated that the die(s) 520 may be arranged differently in various embodiments. For example, for the device 500 including multiple dies 520, the dies 520 may be arranged side-by-side with their respective device faces both facing the substrate 510, or be arranged such that one die is stacked on top of another die.

Referring again to FIG. 3, for the power converter package 300 including multiple switched-capacitor layers stacked vertically, the stacking dies and associated passive components often generate significant heat and result in thermal hotspots due to high-power devices within the packages. To facilitate heat dissipation, the power converter package 300 may further include one or more heat spreader layers within a single switched-capacitor layer, or between two adjacent switched-capacitor layers.

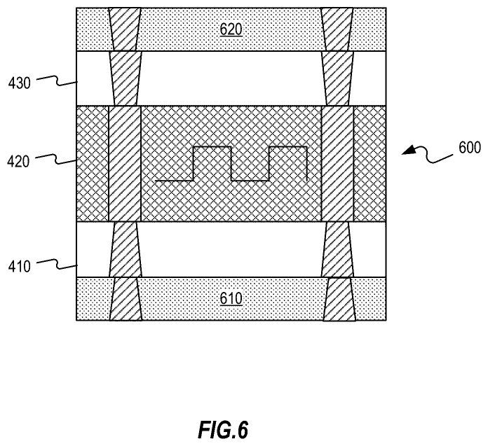

FIG. 6 is a diagram illustrating another exemplary device 600 including heat spreader layers, in accordance with some embodiments of the present disclosure. The device 600 may also be used to implement any of the devices 110a, 110b, and 110c in the power converter package 300 in FIG. 3. Like the device 400 of FIG. 4A, wafer-level stacking technology is applied in the device 600.

In addition to the first active device layer 410, the passive device layer 420, and the second active device layer 430 stacked vertically, the device 600 further includes one or more heat spreader layers 610 and 620. The heat spreader layer 610 is arranged on a bottom side of the device 600, under the first active device layer 410. The heat spreader layer 620 is arrange on a top side of the device 600, over the second active device layer 430. Heat spreader layers 610 and 620 respectively include a thermally conductive insulating material (e.g., SiC, AlN, diamond, etc.) for heat dissipation. Accordingly, heat spreader layers 610 and 620 contribute to transferring the accumulated heat out of the stacked layers, and avoid damages or performance degradation due to heat accumulation in the active device layers 410 and 430 or the passive device layer 420.

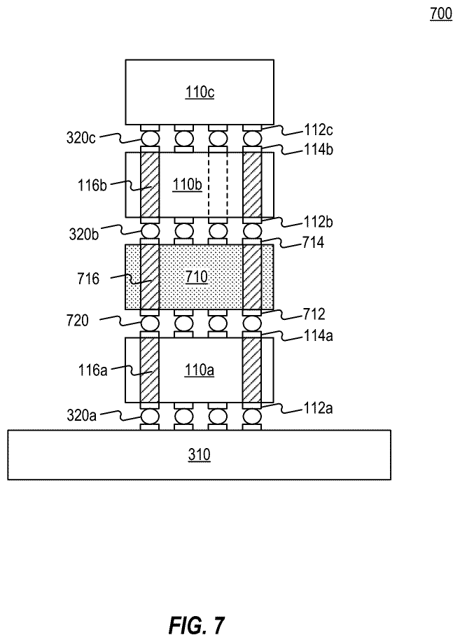

FIG. 7 is a diagram illustrating another exemplary power converter package 700, in accordance with some embodiments of the present disclosure. Compared to the power converter package 300 of FIG. 3, the power converter package 700 further includes a heat spreader layer 710 disposed vertically between two adjacent devices (e.g., devices 110a and 110b).

As shown in FIG. 7, the heat spreader layer 710 may have similar form factor of the switched-capacitor layers, such as devices 110a, 110b and 110c, in the power converter package 700. The heat spreader layer 710 also includes bonding contacts 712 on one surface (e.g., a bottom surface) and bonding contacts 714 on an opposite surface (e.g., a top surface). Bonding contacts 712 communicate, through bondings 720, with one of the two adjacent devices (e.g., device 110a under the heat spreader layer 710), and bonding contacts 714 communicate, through bondings 320b, with the other one of the two adjacent devices (e.g., device 110b over the heat spreader layer 710). One or more through-vias 716 of the heat spreader layer 710 connect corresponding bonding contact(s) 712 and corresponding bonding contact(s) 714. Like the embodiments of FIG. 6, the heat spreader layer 710 may also include a thermally conductive insulating material (e.g., SiC, AlN, diamond, etc.) for heat dissipation. It is noted that other heatsink structures may also be used to implement the heat spreader layers 610, 620, and 710 shown in FIG. 6 and FIG. 7. Embodiments disclosed herein are examples and not meant to limit the present disclosure. For example, the semiconductor device 600 in FIG. 6 can also be connected to a heat sink to transfer the heat from the semiconductor device 600.

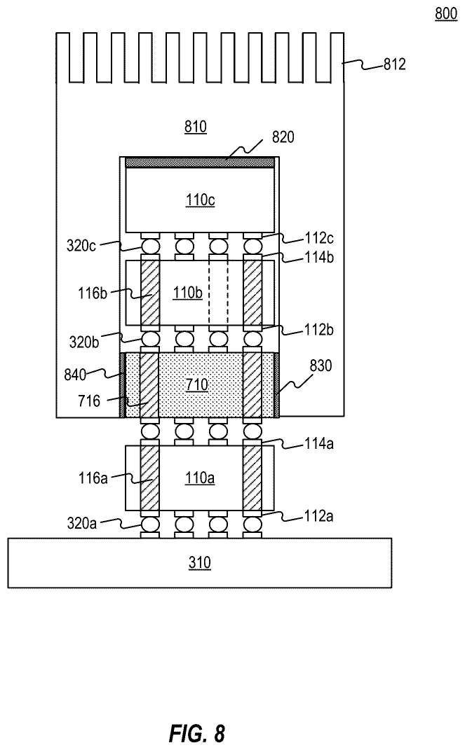

FIG. 8 is a diagram illustrating another exemplary power converter package 800, in accordance with some embodiments of the present disclosure. In the embodiments of FIG. 8, the power converter package 800 further includes a heat sink 810 configured to carry heat away from the devices 110a-110c. The heat sink 810 may be a copper block or an aluminum block, but the present disclosure is not limited thereto. In some embodiments, the heat sink 810 may include one or more heatsink fins 812 extending from a base portion of the heat sink 810 to increase the heat transfer area and further facilitate the heat dissipation through thermal convection. For example, heatsink fins may be elongated, substantially flat members arranged substantially parallel with one another. Accordingly, the heat can be conducted from the devices 110a-110c to the heat sink 810 and the heatsink fins 812, which transfer heat by convection to ambient air. In some embodiments, a heat sink fan may be used for generating an air flow to further enhance the cooling effect of the heat sink 810.

As shown in FIG. 8, the thermal interface material 820 is placed between the top device (e.g., device 110c) of the stacked devices 110a, 110b, and 110c and the heat sink 810. Specifically, the device 110c provides bottom bonding contacts 112c on the bottom surface, and the thermal interface material 820 is in contact with the top surface opposite the bottom surface to facilitate the heat transfer from the device 110c to the heat sink 810. Similarly, the thermal interface material 830 and 840 are placed between the heat spreader layer 710 and the heat sink 810 to facilitate the heat transfer. For example, the heat spreader layer 710 may include a vapor chamber, with the thermal interface material 830 and 840 placed between the vapor chamber wall of the vapor chamber and the heat sink 810. In some other embodiments, microfluidic heat sinks, or other cooling systems may also be used in the power converter package 800. Accordingly, the arrangement of the heat spreader layer 710 and the heat sink 810 in FIG. 8 is merely an example and not meant to limit the disclosure.

In some embodiments, the power converter packages 300, 700, 800 and devices 400, 500, 600 disclosed in FIG. 3-8 can also be applied to implement multi-level power converters, such as a 3-level buck power converter, or any other hybrid converter with a small profile component, but the present disclosure is not limited thereto. Particularly, hybrid converters, such as multi-level power converters or series capacitor buck converters, also include a switched capacitor circuit combined with different topologies.

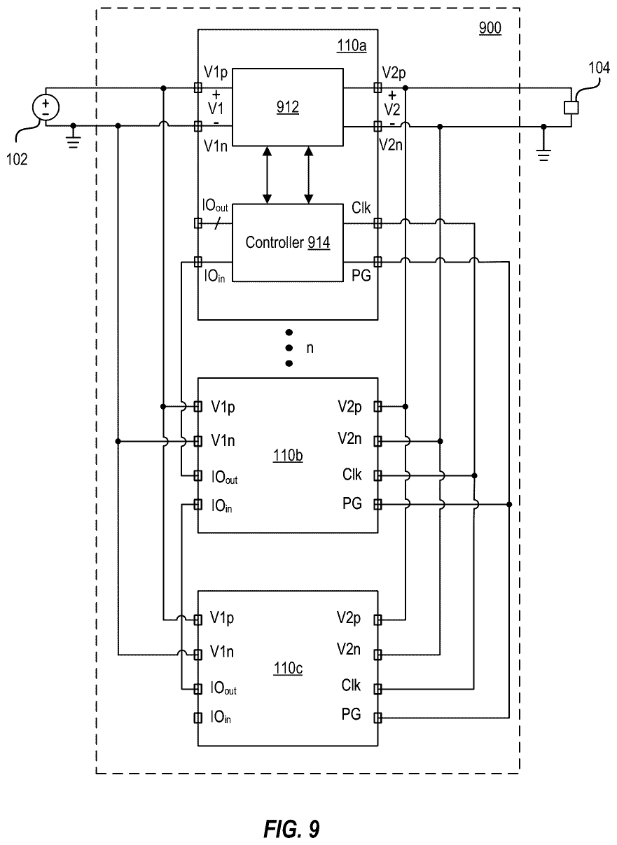

FIG. 9 is a diagram illustrating another exemplary power converter 900, in accordance with some embodiments of the present disclosure. Like the embodiments of FIG. 1, the power converter 900 also includes devices 110a, 110b, and 110c coupled to each other, and each device provides a power module. In the present embodiment, the device 110a includes a multi-level power converter circuit 912 and a controller circuit 914 configured to control the operation of the multi-level power converter circuit 912. Like the power converter 100 of FIG. 1, by using multiple power modules arranged in parallel in the power converter 900, the power converter 900 may achieve higher power rating based on low-cost and low-rating devices. The controller circuit 914 may include the same or similar circuitry of the controller circuit 114 of FIG. 1, which has been discussed in detail above and thus the description is not repeated herein for the sake of brevity.

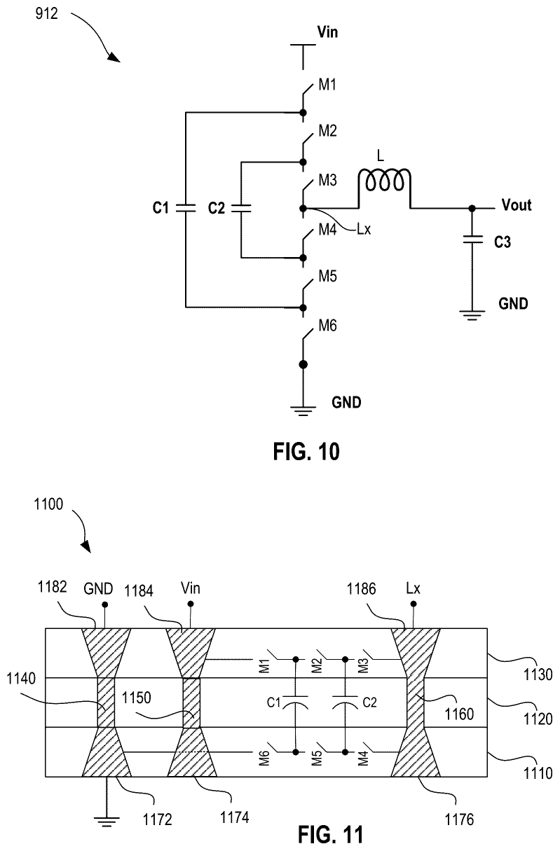

FIG. 10 is a diagram illustrating an exemplary multi-level power converter circuit 912 in the device 110a of FIG. 9, in accordance with some embodiments of the present disclosure. As an example, the multi-level power converter circuit 912 may be a single phase 4-level flying capacitor converter, but the present disclosure is not limited thereto. It would be appreciated that different power converter topologies can be employed for the multi-level power converter circuit 912.

In the example of FIG. 10, the multi-level power converter circuit 912 includes power switches M1, M2, M3, M4, M5, and M6 arranged in a series connection, flying capacitors C1 and C2, an inductor L, which may be a low profile chip inductor having a compact size, and an output capacitor C3. Particularly, each phase leg within the 4-level converter includes 3 cells connected in series, where each cell includes a complimentary switch pair (e.g., switches M1 and M6, switches M2 and M5, and switches M3 and M4) and an associated flying capacitor (e.g., C1 and C2). During the circuit operation, one switch is conducting in each cell at a given time. Accordingly, the multi-level power converter circuit 912 operates at one of eight different states. Depending upon the state, the voltage at a node Lx may be at 4 different levels.

The pulsating voltage at the node Lx is filtered by an LC filter formed by the inductor L and the output capacitor C3. Accordingly, the output voltage Vout, which is the average of the voltage at the node Lx can be produced. The multi-level power converter circuit 912 is configured to alternate between combinations of the states depending upon the desired output voltage Vout. During the operation, the flying capacitors C1 and C2 are charged as much as they are discharged to maintain a constant average voltage across the flying capacitors C1 and C2. Accordingly, the multi-level power converter circuit 912 employs the power switches M1-M6, the flying capacitors C1 and C2, the inductor L, and the output capacitor C3 to convert the input voltage Vin to the output power Vout.

FIG. 11 is a diagram illustrating an exemplary device 1100, in accordance with some embodiments of the present disclosure. The device 1100 shown in FIG. 11 may be used to implement any of the devices 110a, 110b, and 110c in the power converter package 900 in FIG. 9. Like the embodiments of FIG. 4A, the device 1100 is wafer-level stacked and includes a first active device layer 1110, a passive device layer 1120 stacked above the first active device layer 1110, and a second active device layer 1130 stacked above the passive device layer 1120. One or more through-vias 1140, 1150, and 1160 are formed and extend elevationally through the first active device layer 1110, the passive device layer 1120 and the second active device layer 1130. In other words, two active device layers 1110 and 1130 are formed on opposite sides of the passive device layer 1120.

Specifically, the active device layer 1130 may include switches M1, M2, and M3 and the active device layer 1110 may include switches M4, M5, and M6. The passive device layer 1120 may include the flying capacitors C1 and C2. For example, the passive device layer 1120 may be a glass wafer/panel including the flying capacitors C1 and C2. In some embodiments, the inductor L can also be formed in an inductor layer (not shown) within the device 1100 to achieve the multi-level power converter circuit 912 of FIG. 10. The device 1100 provides bottom bonding contacts 1172, 1174, and 1176 on a bottom surface and top bonding contacts 1182, 1184, and 1186 on a top surface opposite the bottom surface for electrical connections to other devices stacked above or below the device 1100. As shown in FIG. 11, through-vias 1140, 1150, and 1160 may be configured to connect corresponding bottom bonding contacts 1172, 1174, and 1176 and top bonding contacts 1182, 1184, and 1186. Accordingly, a stacked, multi-level structure, such as shown in FIG. 11, may allow higher density of capacitors and switches to be fabricated resulting in more compact and higher power-density multi-level power converters.

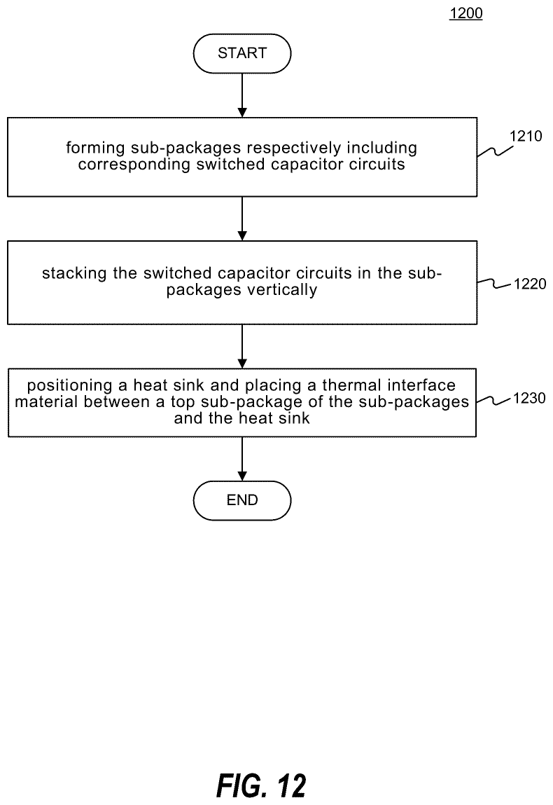

FIG. 12 is a flowchart of a method 1200 for integrated circuit packaging, in accordance with some embodiments of the present disclosure. It is understood that additional operations may be performed before, during, and/or after the method 1200 depicted in FIG. 12, and that some other processes may only be briefly described herein. The method 1200 can be performed to manufacture integrated circuits for power converter applications, such as the power converter 100 in FIG. 1 and the power converter 900 of FIG. 9, using vertically stacked devices, modules, or packages to increase the power density. The method 1200 includes operations 1210, 1220, and 1230.

In the operation 1210, sub-packages respectively including corresponding switched capacitor circuits are formed. A sub-package including a switched capacitor circuit can be realized by various approaches. For example, in the device 400 shown in FIG. 4A, the sub-package can be formed by forming a first active device layer including first switches, forming a passive device layer including capacitors above the first active device layer, and forming a second active device layer including second switches above the passive device layer. In the device 500 shown in FIG. 5, the sub-package can be formed by mounting one or more capacitors of a corresponding switched capacitor circuit on a substrate or a leadframe, mounting one or more dies on the substrate or the leadframe, and depositing an encapsulant over the one or more dies and the one or more capacitors. The one or more dies include switches of the corresponding switched capacitor circuit, and through-vias are through the encapsulant.

In the operation 1220, the switched capacitor circuits in the sub-packages are stacked vertically. For example, first bottom bonding contacts placed on one surface of a first sub-package are bonded to a substrate or an adjacent lower sub-package stacked under the first sub-package, first top bonding contacts placed on another surface opposite the one surface of the first sub-package are bonded to second bottom bonding contacts placed on one surface of a second sub-package. Corresponding one or more of the first bottom bonding contacts and corresponding one or more of the first top bonding contacts are connected by one or more through-vias.

In some embodiments, such as in the power converter package 300 of FIG. 3, the first sub-package includes a first switched capacitor circuit, and the second sub-package includes a second switched capacitor circuit. In some other embodiments, such as in the power converter package 700 of FIG. 7, the second sub-package may include a heat spreader layer. For the second sub-package including the heat spreader layer, second top bonding contacts placed on another surface opposite the one surface of the second sub-package are bonded to third bottom bonding contacts on one surface of a third sub-package including the second switched capacitor circuit.

In the operation 1230, a heat sink is positioned, and a thermal interface material is placed accordingly. Consistent with the discussion associated with the power converter package 800 of FIG. 8, the thermal interface material may be placed between a top sub-package of the sub-packages and the heat sink. In addition, in some embodiments, the thermal interface material is also placed between one or more heat spreader layers of the sub-packages and the heat sink to facilitate the heat transfer. For example, the second sub-package may include a vapor chamber as the heat spreader layer, and the thermal interface material may be placed between a vapor chamber wall of the vapor chamber and the heat sink.

By the operations 1210, 1220, and 1230 discussed above, a power converter package (e.g., power converter package 300 of FIG. 3) having stacked switched capacitor circuits or a power converter package having stacked switched capacitor circuits and one or more heat spreader layers (e.g., power converter package 700 of FIG. 7 or power converter package 800 of FIG. 8) can be obtained. As previously discussed, the finalized package includes vertically stacked modules with improved power density, thermal management characteristics, and simplified electrical connections. Accordingly, the method 1200 is suited for various power conversion applications, such as power converter ICs with stacked charge pump circuits or multi-level power converters.

In summary, by using devices with bonding contacts arranged on both the top surface and the bottom surface, the devices can be stacked on one another to form a power converter package having multiple parallel-connected power modules. Thus, the stacked circuits provide greater output current and higher power density, without increasing the overall package area. The embodiments of the present disclosure are suitable for various apparatus or systems, such as power converters used in modern-day datacenters, but the present disclosure is not limited thereto. The disclosed embodiments can also be used in other power applications or scenarios where the package height is less critical. Electrical signals and/or heat generated in the dies can be transferred via corresponding bonding contacts and through-vias. Accordingly, the obtained power converter package may achieve several desired performance characteristics, including high thermal conductivity. In addition, parallel-connected power modules also provide more flexibility in designing circuits for various power ratings and different applications.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is also intended that the sequence of steps shown in figures are only for illustrative purposes and are not intended to be limited to any particular sequence of steps. As such, those skilled in the art can appreciate that these steps can be performed in a different order while implementing the same method.

It is appreciated that certain features of the specification, which are, for clarity, described in the context of separate embodiments, may also be provided in combination in a single embodiment. Conversely, various features of the specification, which are, for brevity, described in the context of a single embodiment, may also be provided separately or in any suitable sub-combination or as suitable in any other described embodiments of the specification. Certain features described in the context of various embodiments are not to be considered essential features of those embodiments unless the embodiment is inoperative without those elements.

The embodiments may further be described using the following clauses:
1. A power converter package, comprising:
a plurality of devices stacked vertically, the devices comprising:
   a first device comprising a first switched capacitor circuit and providing:
      first bottom bonding contacts on one surface and first top bonding contacts on another surface opposite the one surface; and
      one or more through-vias connecting corresponding one or more of the first bottom bonding contacts and corresponding one or more of the first top bonding contacts; and
   a second device comprising a second switched capacitor circuit and providing second bottom bonding contacts on one surface to be electrically connected to the first top bonding contacts of the first device,
   wherein input terminals of the first and switched capacitor circuits are electrically connected to each other, and output terminals of the first and switched capacitor circuits are electrically connected to each other.
2. The power converter package of clause 1, wherein the first device further comprises:
a first active device layer including a plurality of first switches of the first switched capacitor circuit;
a passive device layer above the first active device layer, the passive device layer including a plurality of capacitors of the first switched capacitor circuit; and
a second active device layer above the passive device layer, the second active device layer including a plurality of second switches of the first switched capacitor circuit.
3. The power converter package of clause 2, wherein the first switches are phase switches, and the second switches are stack switches.
4. The power converter package of clause 2 or clause 3, wherein the passive device layer comprises a glass wafer.
5. The power converter package of any of clauses 2-4, wherein the first device further comprises:
one or more heat spreader layers on a top side or a bottom side of the first device, the one or more heat spreader layers comprising a thermally conductive insulating material.
6. The power converter package of clause 1, wherein the first device further comprises:
a substrate or leadframe;
one or more capacitors of the first switched capacitor circuit mounted on the substrate or leadframe;
one or more dies mounted on the substrate or leadframe, the one or more dies including a plurality of switches of the first switched capacitor circuit; and
an encapsulant deposited over the one or more dies and the one or more capacitors, wherein the one or more through-vias are through the encapsulant.
7. The power converter package of clause 6, wherein the first device further comprises a heat spreader over the one or more dies.
8. The power converter package of any of clauses 1-7, further comprising:
one or more heat spreader layers disposed vertically between two adjacent devices in the plurality of devices, any of the one or more heat spreader layers comprising:
   first bonding contacts on one surface to communicate with one of the two adjacent devices; and
   second bonding contacts on another surface opposite the one surface to communicate with the other one of the two adjacent devices.
9. The power converter package of clause 8, wherein the one or more heat spreader layers comprise a vapor chamber, a thermal interface material being placed between a vapor chamber wall of the vapor chamber and a heat sink.
10. The power converter package of any of clauses 1-9, wherein the plurality of devices are stacked on each other through electrical bonding, thermo-compression bonding, or a hybrid bonding.
11. The power converter package of any of clauses 1-10, wherein a thermal interface material is placed between a top device of the plurality of devices and a heat sink, the top device providing bottom bonding contacts on one surface, the thermal interface material being in contact with another surface opposite the one surface of the top device.
12. The power converter package of any of clauses 1-11, wherein the first device further includes a controller to control operation of the first switched capacitor circuit.
13. The power converter package of any of clauses 1-12, wherein the first device further includes an inductor for a multi-level power converter.
14. An apparatus for power conversion, comprising:
a plurality of switched capacitor circuits respectively arranged in a plurality of integrated circuit packages stacked vertically, the switched capacitor circuits being coupled in parallel to convert a first voltage to a second voltage, wherein at least one package in the plurality of integrated circuit packages comprises:
   bottom bonding contacts on one surface providing connections to a substrate or an adjacent lower package stacked under the package;
   top bonding contacts on another surface opposite the one surface providing connections to an adjacent upper package stacked over the package; and
   one or more through-vias connecting corresponding one or more of the bottom bonding contacts and corresponding one or more of the top bonding contacts.
15. The apparatus of clause 14, wherein:
the plurality of integrated circuit packages includes a top package comprising bottom bonding contacts on one surface providing connections to an adjacent lower package stacked under the top package; and
a thermal interface material is placed between another surface opposite the one surface of the top package and a heat sink.
16. The apparatus of clause 14 or clause 15, further comprising:
one or more controller circuits to control operation of the plurality of switched capacitor circuits, the one or more controller circuits being arranged in one or more of the plurality of integrated circuit packages.
17. The apparatus of clause 16, wherein the one or more controller circuits comprise:
a master controller circuit arranged in a bottom package of the plurality of integrated circuit packages; and
one or more slave controller circuits arranged in one or more packages stacked over the bottom package and electrically connected with the master controller circuit through corresponding bottom bonding contacts and top bonding contacts of the plurality of integrated circuit packages.
18. The apparatus of any of clauses 14-17, wherein the plurality of switched capacitor circuits are controlled by an external controller coupled to the plurality of switched capacitor circuits.
19. The apparatus of any of clauses 14-18, further comprising:
one or more heat spreader layers each disposed vertically between two adjacent integrated circuit packages, a thermal interface material being placed between the one or more heat spreader layers and a heat sink.
20. The apparatus of any of clauses 14-19, further comprising:
a heat sink configured to carry heat away from the plurality of integrated circuit packages, wherein a thermal interface material is placed between a top package of the plurality of integrated circuit packages and the heat sink.
21. A method for integrated circuit packaging, comprising:
stacking a plurality of switched capacitor circuits respectively in a plurality of sub-packages vertically by:
   bonding first bottom bonding contacts placed on one surface of a first sub-package to a substrate or an adjacent lower sub-package stacked under the first sub-package, the first sub-package comprising a first switched capacitor circuit; and
   bonding first top bonding contacts placed on another surface opposite the one surface of the first sub-package to second bottom bonding contacts placed on one surface of a second sub-package, the second sub-package comprising a second switched capacitor circuit or a heat spreader layer, corresponding one or more of the first bottom bonding contacts and corresponding one or more of the first top bonding contacts being connected by one or more through-vias.
22. The method of clause 21, wherein the second sub-package comprises the heat spreader layer, the method further comprising:
bonding second top bonding contacts placed on another surface opposite the one surface of the second sub-package to third bottom bonding contacts on one surface of a third sub-package, the third sub-package comprising the second switched capacitor circuit.
23. The method of clause 21 or clause 22, wherein the second sub-package comprises a vapor chamber as the heat spreader layer, the method further comprising:
positioning a heat sink and placing a thermal interface material between a vapor chamber wall of the vapor chamber and the heat sink.
24. The method of any of clauses 21-23, further comprising:
positioning a heat sink and placing a thermal interface material between a top sub-package of the plurality of sub-packages and the heat sink.
25. The method of any of clauses 21-24, wherein one of the plurality of sub-packages is formed by:
forming a first active device layer including a plurality of first switches;
forming a passive device layer including a plurality of capacitors above the first active device layer; and
forming a second active device layer including a plurality of second switches above the passive device layer.
26. The method of any of clauses 21-25, wherein one of the plurality of sub-packages is formed by:
mounting one or more capacitors of a corresponding switched capacitor circuit on a substrate or leadframe;
mounting one or more dies on the substrate or leadframe, the one or more dies including a plurality of switches of the corresponding switched capacitor circuit; and
depositing an encapsulant over the one or more dies and the one or more capacitors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power converter package, comprising:
a plurality of devices stacked vertically, the devices comprising:
a first device comprising a first switched capacitor circuit and providing:
first bottom bonding contacts on one surface and first top bonding contacts on another surface opposite the one surface; and
one or more through-vias connecting corresponding one or more of the first bottom bonding contacts and corresponding one or more of the first top bonding contacts; and
a second device comprising a second switched capacitor circuit and providing second bottom bonding contacts on one surface to be electrically connected to the first top bonding contacts of the first device,
wherein input terminals of the first and switched capacitor circuits are electrically connected to each other, and output terminals of the first and switched capacitor circuits are electrically connected to each other.

2. The power converter package of claim 1, wherein the first device further comprises:
a first active device layer including a plurality of first switches of the first switched capacitor circuit;
a passive device layer above the first active device layer, the passive device layer including a plurality of capacitors of the first switched capacitor circuit; and
a second active device layer above the passive device layer, the second active device layer including a plurality of second switches of the first switched capacitor circuit.

3. The power converter package of claim 2, wherein the first switches are phase switches, and the second switches are stack switches.

4. The power converter package of claim 3, wherein the passive device layer comprises a glass wafer.

5. The power converter package of claim 2, wherein the first device further comprises:
one or more heat spreader layers on a top side or a bottom side of the first device, the one or more heat spreader layers comprising a thermally conductive insulating material.

6. The power converter package of claim 1, wherein the first device further comprises:
a substrate or leadframe;
one or more capacitors of the first switched capacitor circuit mounted on the substrate or leadframe;
one or more dies mounted on the substrate or leadframe, the one or more dies including a plurality of switches of the first switched capacitor circuit; and
an encapsulant deposited over the one or more dies and the one or more capacitors, wherein the one or more through-vias are through the encapsulant.

7. The power converter package of claim 6, wherein the first device further comprises a heat spreader over the one or more dies.

8. The power converter package of claim 1, further comprising:
one or more heat spreader layers disposed vertically between two adjacent devices in the plurality of devices, any of the one or more heat spreader layers comprising:
first bonding contacts on one surface to communicate with one of the two adjacent devices; and
second bonding contacts on another surface opposite the one surface to communicate with the other one of the two adjacent devices.

9. The power converter package of claim 8, wherein the one or more heat spreader layers comprise a vapor chamber, a thermal interface material being placed between a vapor chamber wall of the vapor chamber and a heat sink.

10. The power converter package of claim 9, wherein the plurality of devices are stacked on each other through electrical bonding, thermo-compression bonding, or a hybrid bonding.

11. The power converter package of claim 1, wherein a thermal interface material is placed between a top device of the plurality of devices and a heat sink, the top device providing bottom bonding contacts on one surface, the thermal interface material being in contact with another surface opposite the one surface of the top device.

12. The power converter package of claim 11, wherein the first device further includes a controller to control operation of the first switched capacitor circuit.

13. The power converter package of claim 12, wherein the first device further includes an inductor for a multi-level power converter.

14. An apparatus for power conversion, comprising:
a plurality of switched capacitor circuits respectively arranged in a plurality of integrated circuit packages stacked vertically, the switched capacitor circuits being coupled in parallel to convert a first voltage to a second voltage, wherein at least one package in the plurality of integrated circuit packages comprises:
bottom bonding contacts on one surface providing connections to a substrate or an adjacent lower package stacked under the package;
top bonding contacts on another surface opposite the one surface providing connections to an adjacent upper package stacked over the package; and
one or more through-vias connecting corresponding one or more of the bottom bonding contacts and corresponding one or more of the top bonding contacts.

15. The apparatus of claim 14, wherein:
the plurality of integrated circuit packages includes a top package comprising bottom bonding contacts on one surface providing connections to an adjacent lower package stacked under the top package; and
a thermal interface material is placed between another surface opposite the one surface of the top package and a heat sink.

16. The apparatus of claim 14, further comprising:
one or more controller circuits to control operation of the plurality of switched capacitor circuits, the one or more controller circuits being arranged in one or more of the plurality of integrated circuit packages.

17. The apparatus of claim 16, wherein the one or more controller circuits comprise:
a master controller circuit arranged in a bottom package of the plurality of integrated circuit packages; and
one or more slave controller circuits arranged in one or more packages stacked over the bottom package and electrically connected with the master controller circuit through corresponding bottom bonding contacts and top bonding contacts of the plurality of integrated circuit packages.

18. The apparatus of claim 14, wherein the plurality of switched capacitor circuits are controlled by an external controller coupled to the plurality of switched capacitor circuits.

19. The apparatus of claim 14, further comprising:
one or more heat spreader layers each disposed vertically between two adjacent integrated circuit packages, a thermal interface material being placed between the one or more heat spreader layers and a heat sink.

20. The apparatus of claim 14, further comprising:
a heat sink configured to carry heat away from the plurality of integrated circuit packages, wherein a thermal interface material is placed between a top package of the plurality of integrated circuit packages and the heat sink.

21. A method for integrated circuit packaging, comprising:
stacking a plurality of switched capacitor circuits respectively in a plurality of sub-packages vertically by:
bonding first bottom bonding contacts placed on one surface of a first sub-package to a substrate or an adjacent lower sub-package stacked under the first sub-package, the first sub-package comprising a first switched capacitor circuit; and
bonding first top bonding contacts placed on another surface opposite the one surface of the first sub-package to second bottom bonding contacts placed on one surface of a second sub-package, the second sub-package comprising a second switched capacitor circuit or a heat spreader layer, corresponding one or more of the first bottom bonding contacts and corresponding one or more of the first top bonding contacts being connected by one or more through-vias.

22. The method of claim 21, wherein the second sub-package comprises the heat spreader layer, the method further comprising:
bonding second top bonding contacts placed on another surface opposite the one surface of the second sub-package to third bottom bonding contacts on one surface of a third sub-package, the third sub-package comprising the second switched capacitor circuit.

23. The method of claim 21, wherein the second sub-package comprises a vapor chamber as the heat spreader layer, the method further comprising:
positioning a heat sink and placing a thermal interface material between a vapor chamber wall of the vapor chamber and the heat sink.

24. The method of claim 21, further comprising:
positioning a heat sink and placing a thermal interface material between a top sub-package of the plurality of sub-packages and the heat sink.

25. The method of claim 21, wherein one of the plurality of sub-packages is formed by:
forming a first active device layer including a plurality of first switches;
forming a passive device layer including a plurality of capacitors above the first active device layer; and
forming a second active device layer including a plurality of second switches above the passive device layer.

26. The method of claim 21, wherein one of the plurality of sub-packages is formed by:
mounting one or more capacitors of a corresponding switched capacitor circuit on a substrate or leadframe;
mounting one or more dies on the substrate or leadframe, the one or more dies including a plurality of switches of the corresponding switched capacitor circuit; and
depositing an encapsulant over the one or more dies and the one or more capacitors.
